(19) United States
(12) Patent Application Publication
(10) Pub. No.: US 2014/0209895 A1
(43) Pub. Date: Jul. 31, 2014

(54) ARRAY SUBSTRATE, FABRICATION METHOD THEREOF AND DISPLAY DEVICE

(71) Applicants: BOE TECHNOLOGY GROUP CO., LTD., Beijing (CN); HEFEI BOE OPTOELECTRONICS TECHNOLOGY CO., LTD., Hefei (CN)

(72) Inventors: Hui WANG, Beijing (CN); Xiangyan XU, Beijing (CN)

(21) Appl. No.: 14/142,682

(22) Filed: Dec. 27, 2013

(30) Foreign Application Priority Data
Jan. 28, 2013 (CN) 201310032587.X

(51) Int. Cl. H01L 27/12

(52) U.S. Cl. CPC H01L 27/1225; H01L 27/127
USPC 257/43; 438/104

(57) ABSTRACT

The invention provides an array substrate, a fabrication method thereof and a display device. The array substrate comprises a base substrate; a gate layer which is disposed on the base substrate and comprises a gate; a gate insulating layer disposed on the gate layer; a source layer which is disposed on the gate insulating layer and comprises a source; a metal oxide semiconductor layer which is disposed on the source layer and the gate insulating layer and comprises an active layer, wherein the source is in direct contact with the active layer; and a pixel electrode layer in direct contact with the active layer. A position where the gate is formed in the gate layer corresponds to a position between the source and a contacting portion of the pixel electrode layer with the active layer.

### FIELD OF THE INVENTION

The present invention relates to the field of display technologies, and more particularly, to an array substrate, a fabrication method thereof and a display device.

### BACKGROUND OF THE INVENTION

With the rapid development of display technologies, sizes of display devices are continuously increasing, and frequencies of drive circuits are continuously increasing as well. As a result, Thin Film Transistors (TFTs) with a higher mobility are required. Herein, mobility is an average drift velocity of charge carriers (electrons and holes) under the action of an electric field, that is, the moving speed of charge carriers under the action of an electric field. The faster the charge carriers move, the larger the mobility is; the slower the charge carriers move, the smaller the mobility is.

As the mobility of existing amorphous TFTs cannot meet the requirements of large scale display devices, polysilicon TFTs and metal oxide TFTs having high mobility attract much attention, and metal oxide semiconductor TFTs (such as Indium Gallium Zinc Oxide (IGZO) TFTs) are widely used in the display devices for having high mobility and simple fabrication processes, and being transparent.

Currently, the structures of metal oxide TFTs are mainly divided into Etch Stop type, Back Channel Etch type and Coplanar type. During the course of fabricating a TFT array substrate, an Etch Stop type metal oxide TFT has simple fabrication process but requires an additional photolithography process to form the etch stop layer, thereby increasing the fabrication process procedure of the metal oxide TFT; a back channel etch type metal oxide TFT has no protection layer provided on the metal oxide semiconductor layer, the metal oxide semiconductor layer is easily damaged when forming the source/drain metal electrode, thereby harming the performance of the metal oxide TFT; a coplanar metal oxide TFT prevents the metal oxide semiconductor layer from being damaged during the process of forming the source/drain metal electrode and has one less photolithography process in comparison with an etch stop type metal oxide TFT, which reduces investment of preparation and fabrication, but as the resistance between the drain, the metal oxide semiconductor layer and the pixel electrode layer is relative larger, thereby degrading the display performance of the metal oxide TFT.

### SUMMARY OF THE INVENTION

Embodiments of the present invention provide an array substrate, a fabrication method thereof and a display device, which may prevent the metal oxide semiconductor layer from being damaged when forming the source/drain metal electrode. Meanwhile, the pixel electrode layer is in direct contact with the metal oxide semiconductor layer and no drain metal is required, thereby reducing the resistance between the metal oxide semiconductor layer and the pixel electrode layer, and greatly improving the display performance of the display device.

To achieve the above objectives, according an aspect of the present invention, an array substrate is provided, which comprises:

a base substrate;

a gate layer which is disposed on the base substrate and comprises a gate;

a gate insulating layer disposed on the gate layer;

a source layer which is disposed on the gate insulating layer and comprises a source;

a metal oxide semiconductor layer which is disposed on the source layer and the gate insulating layer and comprises an active layer, wherein the source is in direct contact with the active layer; and

a pixel electrode layer in direct contact with the active layer;

wherein, a position where the gate is formed in the gate layer corresponds to a position between the source and a contacting portion of the pixel electrode layer with the active layer.

The pixel electrode layer may be disposed on the metal oxide semiconductor layer, or disposed between the metal oxide semiconductor layer and the gate insulating layer.

The array substrate may further comprise an insulating layer disposed on the metal oxide semiconductor layer.

A via may be formed in the insulating layer, the pixel electrode layer is disposed on the insulating layer and in direct contact with the active layer through the via.

A material of the metal oxide semiconductor layer may be IGZO.

According to another aspect of the present invention, a display device is provided, which comprises an array substrate of the present invention.

According to still another aspect of the present invention, a fabrication method of an array substrate is provided, which comprises the steps of:

forming a gate layer comprising a gate on a base substrate;

forming a gate insulating layer on the gate layer;

forming a source layer comprising a source on the gate insulating layer;

forming a metal oxide semiconductor layer comprising an active layer on the source layer and the gate insulating layer, wherein the source is in direct contact with the active layer; and

forming a pixel electrode layer on the metal oxide semiconductor layer;

wherein, the source is in direct contact with the active layer, and

a position where the gate is formed in the gate layer corresponds to a position between the source and a contacting portion of the pixel electrode layer with the active layer.

The method may further comprise the steps of:

forming an insulating layer on the metal oxide semiconductor layer before forming the pixel electrode layer on the metal oxide semiconductor layer;

forming a via in the insulating layer so as to partially expose the metal oxide semiconductor layer; and

forming the pixel electrode layer on the metal oxide semiconductor layer, such that the pixel electrode layer is in direct contact with the active layer through the via.

According to another aspect of the present invention, a fabrication method of an array substrate is provided, which comprises the steps of:

forming a gate layer comprising a gate on a base substrate;

forming a gate insulating layer on the gate layer;

forming a source layer and a pixel electrode layer on the gate insulating layer, the source layer comprising a source; and

forming a metal oxide semiconductor layer comprising an active layer on the source layer, the gate insulating layer and the pixel electrode layer;

wherein, the source is in direct contact with the active layer, the pixel electrode layer is in direct contact with the metal oxide semiconductor layer, and a position where the gate is formed in the gate layer corresponds to a position between the source and a contacting portion of the pixel electrode layer with the active layer.

According to the array substrate and fabrication method thereof, and the display device of the present invention, the metal oxide semiconductor layer is formed on the gate insulating layer after forming the source, which can prevent the metal oxide semiconductor layer from being damaged when forming the source/drain metal electrode. Meanwhile, the pixel electrode layer is in direct contact with the metal oxide semiconductor layer and no drain metal is required, thereby reducing the resistance between the metal oxide semiconductor layer and the pixel electrode layer, and greatly improving the display performance of the display device.

### BRIEF DESCRIPTION OF THE DRAWINGS

FIG. 1 is a partially cutaway schematic view of an array substrate according to an embodiment of the present invention;

FIG. 2 is a top view of an array substrate according to an embodiment of the present invention;

FIG. 3 is a partially cutaway schematic view of an array substrate according to another embodiment of the present invention;

FIG. 4 is a top view of an array substrate according to another embodiment of the present invention;

FIG. 5 is a flow chart of a fabrication method of an array substrate according to an embodiment of the present invention;

FIGS. 6 to 12 are partially cutaway schematic views formed by respective steps during the fabrication of an array substrate according to an embodiment of the present invention;

FIG. 13 is a flow chart of a fabrication method of an array substrate according to another embodiment of the present invention; and

FIGS. 14 to 16 are partially cutaway schematic views formed by respective steps during the fabrication of an array substrate according to another embodiment of the present invention.

### DETAILED DESCRIPTION OF EMBODIMENTS

In the following, technical solutions in embodiments of the present invention will be described clearly and completely with reference to the drawings in the embodiments of the present invention. Obviously, the described embodiments are only a part of the embodiments of the present invention, but not all implementations. Based on the embodiments of the present invention, other implementations obtained by the person skilled in the art are within the protection scope of the present invention.

An array substrate is provided according to an embodiment of the present invention, it comprises: a base substrate; a gate layer which is disposed on the base substrate and comprises a gate; a gate insulating layer disposed on the gate layer; a source layer which is disposed on the gate insulating layer and comprises a source; a metal oxide semiconductor layer which is disposed on the source layer and the gate insulating layer and comprises an active layer, wherein the source is in direct contact with the active layer; and a pixel electrode layer in direct contact with the active layer; wherein, a position where the gate is formed in the gate layer corresponds to a position between the source and a contacting portion of the pixel electrode layer with the active layer.

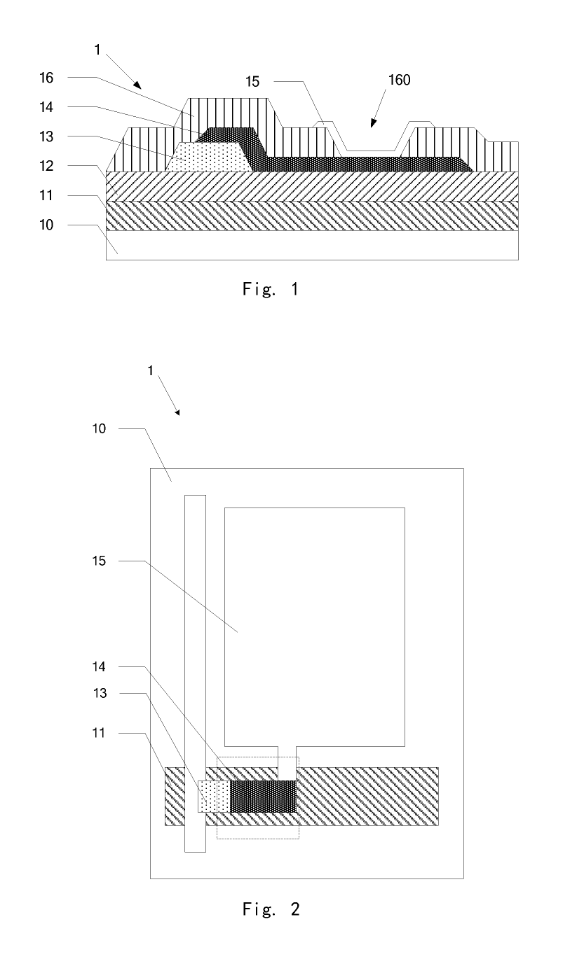

FIG. 1 is a partially cutaway schematic view of an array substrate 1 according to an embodiment of the present invention. FIG. 2 is a top view of the array substrate 1 according to this embodiment.

With reference to FIGS. 1 and 2, the array substrate 1 comprises: a base substrate 10; a gate layer 11 which is disposed on the base substrate 10 and comprises a gate; a gate insulating layer 12 disposed on the gate layer 11; a source layer 13 which is disposed on the gate insulating layer 12 and comprises a source; a metal oxide semiconductor layer 14 which is disposed on the source layer 13 and the gate insulating layer 12 and comprises an active layer, wherein the source is in direct contact with the active layer; and a pixel electrode layer 15 in direct contact with the active layer. A position where the gate is formed in the gate layer 15 corresponds to a position between the source and a contacting portion of the pixel electrode layer 15 with the active layer.

In addition, as illustrated in FIG. 1, the pixel electrode layer 15 is disposed on the metal oxide semiconductor layer 14, and the array substrate 1 further comprises an insulating layer 16 disposed on the metal oxide semiconductor layer 14. A via 160 is formed in the insulating layer 16, the pixel electrode layer 15 is in direct contact with the active layer through the via.

The metal oxide semiconductor layer 14 may be made of IGZO, and the insulating layer 16 and the gate insulating layer 12 may be made of silicon oxide. In addition, the insulating layer 16 and the gate insulating layer 12 may be made of other materials, as long as they can protect the metal oxide semiconductor layer 14 and the gate layer 11, which is not limited herein. According to this embodiment, no drain is disposed on the gate insulating layer 12, and instead, the pixel electrode layer 15 is in direct contact with the metal oxide semiconductor layer 14. The metal oxide semiconductor layer 14 may be made of IGZO, and when the TFT is turned on, the source and the pixel electrode layer 15 are conducted through the metal oxide semiconductor layer. As no drain is provided, the resistance between the metal oxide semiconductor layer 14 and the pixel electrode layer 15 is reduced, thereby significantly improving the display performance of the display device.

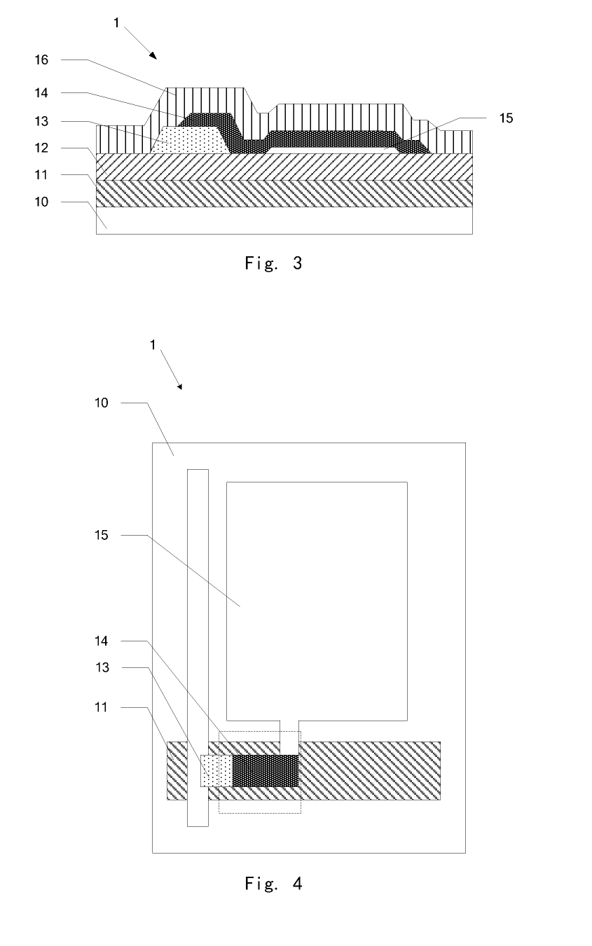

FIG. 3 is a partially cutaway schematic view of another array substrate 1 according to an embodiment of the present invention. FIG. 4 is a top view of the array substrate 1 according to this embodiment. The embodiment illustrated in FIGS. 3 and 4 differs from the embodiment illustrated in FIGS. 1 and 2 only in that the pixel electrode 15 is formed at a different position. Therefore, the embodiment illustrated in FIGS. 3 and 4 can achieve the same technical effect as the embodiment illustrated in FIGS. 1 and 2.

With reference to FIGS. 3 and 4, the array substrate 1 comprises: a base substrate 10; a gate layer 11 disposed on the base substrate 10; a gate insulating layer 12 disposed on the gate layer 11; a source layer 13 which is disposed on the gate insulating layer 12 and comprises a source; a metal oxide semiconductor layer 14 which is disposed on the source layer 13 and the gate insulating layer 12 and comprises an active layer, wherein the source is in direct contact with the active layer; and a pixel electrode layer 15 in direct contact with the active layer. A position where the gate is formed in the gate layer 15 corresponds to a position between the source and a contacting portion of the pixel electrode layer 15 with the active layer.

In addition, as illustrated in FIG. 3, the pixel electrode layer 15 is disposed between the metal oxide semiconductor layer 14 and the gate insulating layer 12, and the pixel electrode layer 15 is in direct contact with the metal oxide semiconductor layer 14.

The array substrate 1 may further comprise a insulating layer 16 disposed on the metal oxide semiconductor layer 14. The metal oxide semiconductor layer 14 may be made of IGZO, and the insulating layer 16 and the gate insulating layer 12 may be made of silicon oxide. In addition, the insulating layer 16 and the gate insulating layer 12 may be made of other materials, as long as they can protect the metal oxide semiconductor layer 14 and the gate layer 11, which is not limited herein.

According to the embodiment illustrated in FIGS. 3 and 4, the pixel electrode layer 15 is disposed between the metal oxide semiconductor layer 14 and the gate insulating layer 12, and therefore no via needs to be formed in the insulating layer 16.

The only difference between the above two embodiments is: the pixel electrode layer 15 in the embodiment illustrated in FIGS. 1 and 2 is disposed on the metal oxide semiconductor layer 14, while the pixel electrode layer 15 in the embodiment illustrated in FIGS. 3 and 4 is disposed under the metal oxide semiconductor layer 14. However, both embodiments may form direct contact between the pixel electrode layer 15 and the metal oxide semiconductor layer 14. When the TFT is turned on, the source and the pixel electrode layer 15 are conducted through the metal oxide semiconductor layer. As no drain is provided, the resistance between the metal oxide semiconductor layer 14 and the pixel electrode layer 15 is reduced, thereby significantly improving the display performance of the display device.

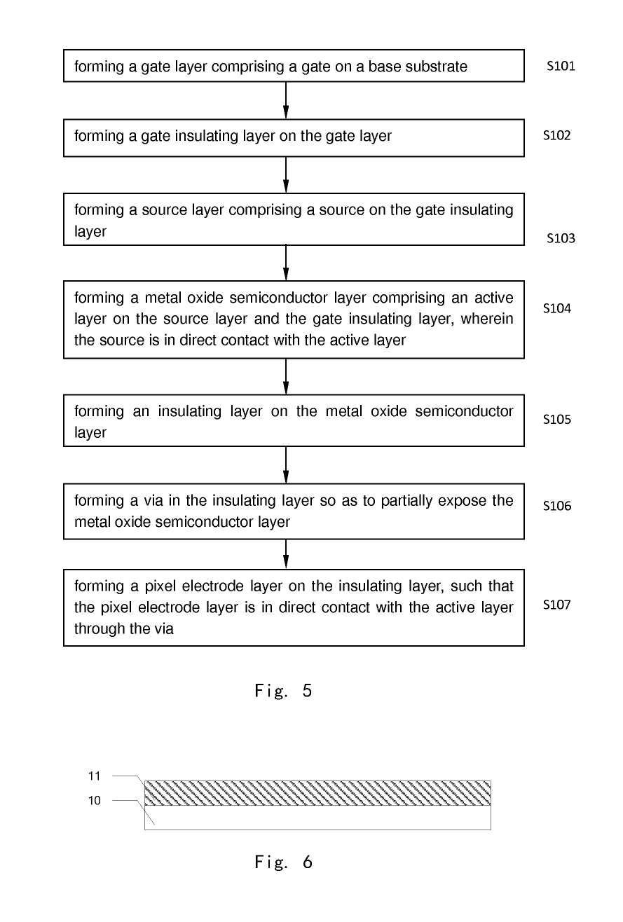

FIG. 5 is a flow chart of a fabrication method of an array substrate according to an embodiment of the present invention. As illustrated in FIG. 5, the method comprises the steps of:

forming a gate layer comprising a gate on a base substrate (S101);

forming a gate insulating layer on the gate layer (S102);

forming a source layer comprising a source on the gate insulating layer (S103);

forming a metal oxide semiconductor layer comprising an active layer on the source layer and the gate insulating layer, wherein the source is in direct contact with the active layer (S104);

forming an insulating layer on the metal oxide semiconductor layer (S105);

forming a via in the insulating layer so as to partially expose the metal oxide semiconductor layer (S106);

forming a pixel electrode layer on the insulating layer, such that the pixel electrode layer is in direct contact with the active layer through the via (S107);

wherein, a position where the gate is formed in the gate layer corresponds to a position between the source and a contacting portion of the pixel electrode layer with the active layer.

FIGS. 6 to 12 are partially cutaway schematic views formed by respective steps during the fabrication of the array substrate according to the embodiment of the present invention.

With reference to FIGS. 5 and 6, when fabricating the array substrate, a gate metal film is first formed on the pre-cleansed base substrate 10 through for example a sputtering process, and then the gate layer 11 comprising the gate is formed on the base substrate 10 through masking and wet etching processes. Herein wet etching is an etching method, which is a technique that a material to be etched is immersed in an etchant.

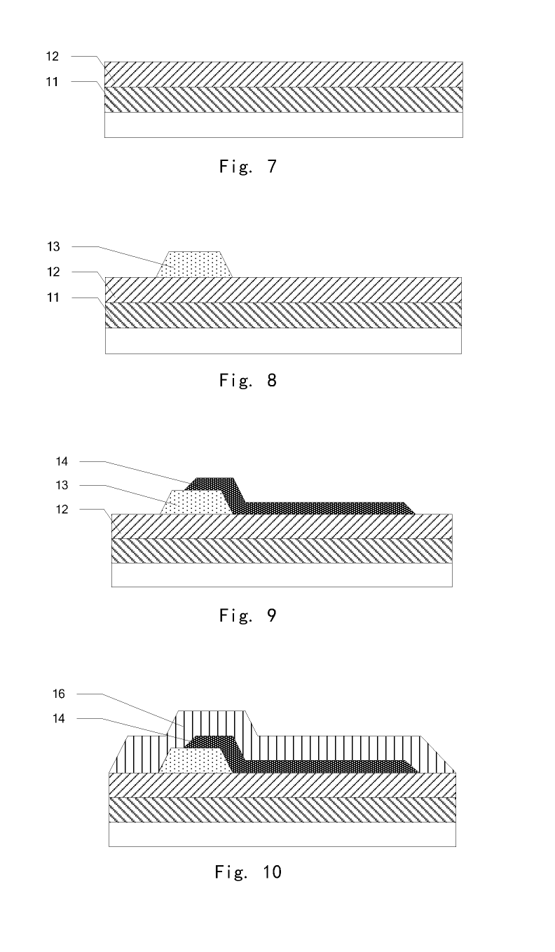

With reference to FIGS. 5 and 7, the gate insulating layer 12 is formed on the gate layer 11 through for example Plasma Enhanced Chemical Vapor Deposition (PECVD) method, so as to protect the gate layer 11 from being damaged, and the gate insulating layer 12 also has an insulation function. The gate insulating layer 12 may be made of silicon oxide or other insulation material, as long as it can protect the gate layer 11, which is not limited herein.

With reference to FIGS. 5 and 8, a metal film is formed on the gate insulating layer 12 through for example a sputtering process, then the source layer 13 comprising the source is formed on the gate insulating layer 12 through masking and wet etching processes, and the source is formed above the gate insulating layer 11.

With reference to FIGS. 5 and 9, a metal oxide semiconductor film is formed on the source layer 13 and the gate insulating layer 12 through for example a sputtering process, and the metal oxide semiconductor layer 14 comprising the active layer is formed on the source layer 13 and the gate insulating layer 12 through masking and wet etching processes. The source is in direct contact with the active layer. A material for forming the metal oxide semiconductor layer 14 may be IGZO.

As the source has already been formed on the gate insulating layer 12 before forming the metal oxide semiconductor layer 14, it can prevent the metal oxide semiconductor layer 14 from being damaged when forming the source, thereby protecting the integrity of the metal oxide semiconductor layer 14.

With reference to FIGS. 5 and 10, the insulating layer 16 is formed on the metal oxide semiconductor layer 14 through for example PECVD method, so as to protect the metal oxide semiconductor layer 14 from being damaged, and the insulating layer 16 also has an insulation function. A material for forming the insulating layer 16 preferably is silicon oxide. In addition, the material for forming the insulating layer 16 may also be other insulation materials, as long as it can protect the metal oxide semiconductor layer 14, Which is not limited herein.

With reference to FIGS. 5 and 11, the via 160 is formed in the insulating layer 16 through for example masking and dry etching processes so as to partially expose the metal oxide semiconductor layer 14. Herein dry etching is a technique that a film is etched by using plasma, and by choosing a suitable gas, the gas may react with the material more rapidly, so as to achieve etching removal.

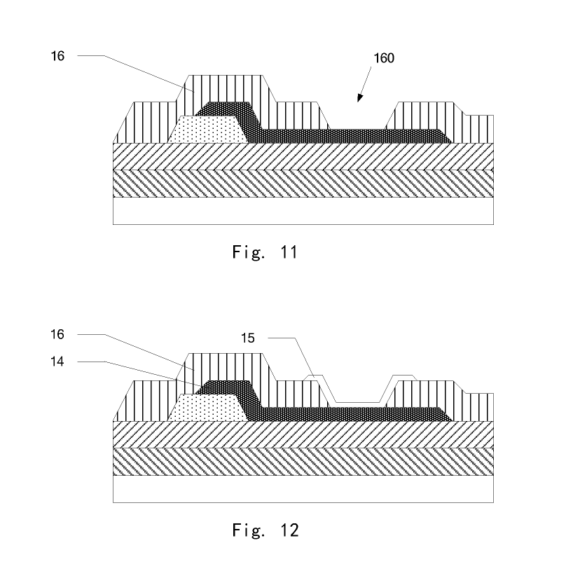

With reference to FIGS. 5 and 12, a pixel electrode film is formed on the insulating layer 16 through for example a sputtering process, and the pixel electrode layer 15 is formed on the metal oxide semiconductor layer 14 through masking and wet etching processes. The pixel electrode layer 15 is in direct contact with the active layer through the via 160, and a position where the gate is formed in the gate layer 11 corresponds to a position between the source and a contacting portion of the pixel electrode layer with the active layer.

According to the fabrication method of the array substrate of the embodiment of the invention, no drain is disposed on the gate insulating layer 12, and instead, the pixel electrode layer 15 is in direct contact with the metal oxide semiconductor layer 14. The metal oxide semiconductor layer 14 may be made of IGZO. When the TFT is turned on, the source and the pixel electrode layer 15 are conducted through the metal oxide semiconductor layer. As no drain is provided, the resistance between the metal oxide semiconductor layer 14 and the pixel electrode layer 15 is reduced, thereby significantly improving the display performance of the display device.

FIG. 13 is a flow chart of a fabrication method of an array substrate according to another embodiment of the present invention. As illustrated in FIG. 13, the method comprises the steps of:

forming a gate layer comprising a gate on a base substrate (S201);

forming a gate insulating layer on the gate layer (S202);

forming a source layer and a pixel electrode layer on the gate insulating layer, the source layer comprising a source (S203);

forming a metal oxide semiconductor layer comprising an active layer on the source layer, the gate insulating layer and the pixel electrode layer (S204);

forming an insulating layer on the metal oxide semiconductor layer (S205);

wherein, the source is in direct contact with the active layer, the pixel electrode layer is in direct contact with the metal oxide semiconductor layer, and a position where the gate is formed in the gate layer corresponds to a position between the source and a contacting portion of the pixel electrode layer with the active layer.

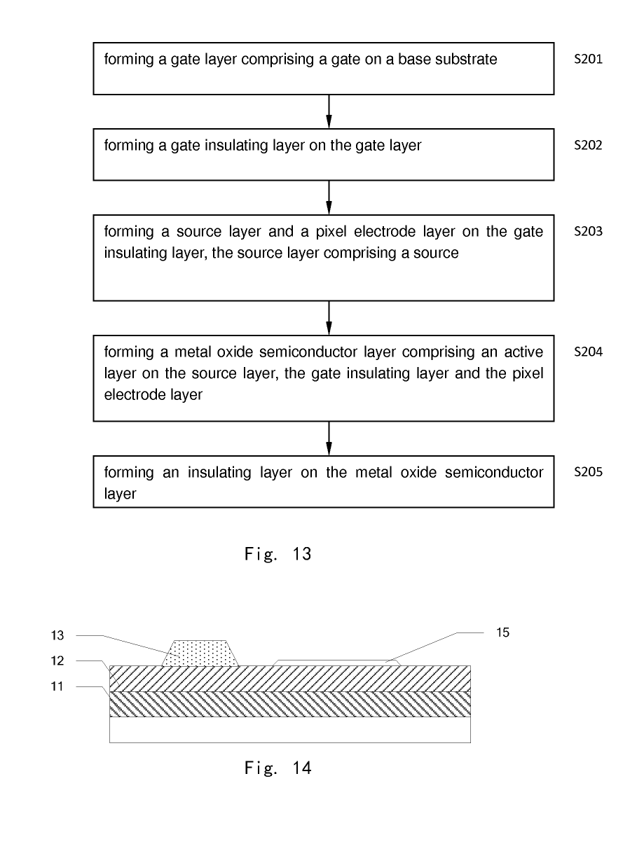

Steps S201 and S202 are substantially the same as the steps S101 and S102 of the embodiment described with reference to FIGS. 5 and 12, respectively, and therefore the description thereof is omitted. FIGS. 14 to 16 are partially cutaway schematic views formed by the remaining steps during the fabrication of the array substrate according to this embodiment.

With reference to FIGS. 13 and 14, a pixel electrode film is formed on the gate insulating layer 12 through for example a sputtering process, and the pixel electrode layer 15 is formed on the gate insulating layer 12 through masking and wet etching processes; a metal film is formed on the gate insulating layer 12 through for example a sputtering process, and then the source layer 13 comprising the source is formed on the gate insulating layer 12 through masking and wet etching processes.

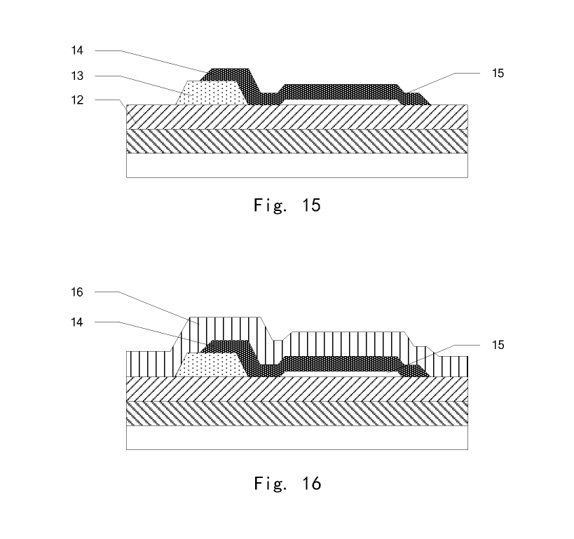

With reference to FIGS. 13 and 15, a metal oxide semiconductor film is formed on the source layer 13, the gate insulating layer 12 and the pixel electrode layer 15 through for example a sputtering process, and the metal oxide semiconductor layer 14 comprising the active layer is formed on the source layer 13, the gate insulating layer 12 and the pixel electrode layer 15 through masking and wet etching processes. The source is in direct contact with the active layer, the pixel layer 15 is in direct contact with the metal oxide semiconductor layer 14, and a position where the gate is formed in the gate layer 11 corresponds to a position between the source and a contacting portion of the pixel electrode layer with the active layer. A material for forming the metal oxide semiconductor layer 14 may be IGZO.

As the source has already been formed on the gate insulating layer 12 through etching before forming the metal oxide semiconductor layer 14, it prevents the metal oxide semiconductor layer 14 from being damaged when forming the source, thereby protecting the integrity of the metal oxide semiconductor layer 14.

With reference to FIGS. 13 and 16, the insulating layer 16 is formed on the metal oxide semiconductor layer 14 through for example PECVD method, so as to protect the metal oxide semiconductor layer 14 under the insulating layer 16 from being damaged, and the insulating layer 16 also has an insulation function. A material for forming the insulating layer 16 may be other insulation materials, as long as it can protect the metal oxide semiconductor layer 14, which is not limited herein.

Since the pixel electrode layer 15 of the array substrate fabricated according to this embodiment is disposed under the metal oxide semiconductor layer 14 and the insulating layer 16, portions of the metal oxide semiconductor layer 14 and the insulating layer 16 in a display region need to be removed through etching and peeling after forming the metal oxide semiconductor layer 14 and the insulating layer 16, so as to expose the pixel electrode layer 15 in a soldering pad region.

It should be noted that, according to the fabrication methods of the array substrate of the embodiments of the present invention, as no drain is disposed on the gate insulating layer 12, and instead, the pixel electrode layer 15 is in direct contact with the metal oxide semiconductor layer 14, no drain is required. As the metal oxide semiconductor layer 14 may be made of IGZO, when the TFT is turned on, the IGZO is driven to be conductive, such that the source and the pixel electrode layer 15 are conducted through the metal oxide semiconductor layer 14, which achieves the same function as a drain. Meanwhile, as no drain is provided, the resistance between the metal oxide semiconductor layer 14 and the pixel electrode layer 15 is reduced, thereby significantly improving the display performance of the display device.

In the present invention, although description has been made by taking IGZO as an typical example of the metal oxide, the person skilled should understand that other metal oxides such as IGO or the like may also be used as channel layer of the TFT. In addition, although description has been made by taking silicon oxide as an example of the material of the insulating layer, the person skilled in the art should understand that other insulation materials may also be used. In addition, description has been made by taking an example that an electrode of the TFT connected to the data line is the source, an electrode of the TFT connected to the pixel electrode is the omitted drain, however, the person skilled in the art should understand that source and drain of a TFT are exchangeable, which is an equivalent implementation of the embodiments described in the present invention.

The array substrate of the present invention may be applied to various display devices. These display devices may be LCD devices, for example products and components having a display function, such as a liquid crystal display, a liquid crystal television, a digital photo frame, a mobile phone, a tablet PC. In addition, the display devices may also be Organic Light-Emitting Diode (OLED) display devices.

What are described above are only specific implementations of the present invention, however, the protection scope of the present invention is not limited thereto. Various modifications and variations which can be easily thought of by the person skilled in the art within the disclosure of the present invention should be within the protection scope of the present invention. Therefore, the protection scope of the present invention is defined by the appended claims.

1. An array substrate, comprising:
a base substrate;
a gate layer which is disposed on the base substrate and comprises a gate;
a gate insulating layer disposed on the gate layer;
a source layer which is disposed on the gate insulating layer and comprises a source;
a metal oxide semiconductor layer which is disposed on the source layer and the gate insulating layer and comprises an active layer, wherein the source is in direct contact with the active layer; and
a pixel electrode layer in direct contact with the active layer,
wherein, a position where the gate is formed in the gate layer corresponds to a position between the source and a contacting portion of the pixel electrode layer with the active layer.

2. The array substrate of claim 1, wherein,
the pixel electrode layer is disposed on the metal oxide semiconductor layer, or disposed between the metal oxide semiconductor layer and the gate insulating layer.

3. The array substrate of claim 1, further comprising an insulating layer disposed on the metal oxide semiconductor layer.

4. The array substrate of claim 3, wherein a via is formed in the insulating layer, the pixel electrode layer is disposed on the insulating layer and in direct contact with the active layer through the via.

5. The array substrate of claim 1, wherein a material of the metal oxide semiconductor layer is IGZO.

6. The array substrate of claim 2, wherein a material of the metal oxide semiconductor layer is IGZO.

7. The array substrate of claim 3, wherein a material of the metal oxide semiconductor layer is IGZO.

8. The array substrate of claim 4, wherein a material of the metal oxide semiconductor layer is IGZO.

9. A display device comprising an array substrate, the array substrate comprises:
a base substrate;
a gate layer which is disposed on the base substrate and comprises a gate;
a gate insulating layer disposed on the gate layer;
a source layer which is disposed on the gate insulating layer and comprises a source;
a metal oxide semiconductor layer which is disposed on the source layer and the gate insulating layer and comprises an active layer, wherein the source is in direct contact with the active layer; and
a pixel electrode layer in direct contact with the active layer,
wherein, a position where the gate is formed in the gate layer corresponds to a position between the source and a contacting portion of the pixel electrode layer with the active layer.

10. The display device of claim 9, wherein,
the pixel electrode layer is disposed on the metal oxide semiconductor layer, or disposed between the metal oxide semiconductor layer and the gate insulating layer.

11. The display device of claim 9, wherein the array substrate further comprises an insulating layer disposed on the metal oxide semiconductor layer.

12. The display device of claim 11, wherein a via is formed in the insulating layer, the pixel electrode layer is disposed on the insulating layer and in direct contact with the active layer through the via.

13. The display device of claim 9, wherein a material of the metal oxide semiconductor layer is IGZO.

14. The display device of claim 10, wherein a material of the metal oxide semiconductor layer is IGZO.

15. The display device of claim 11, wherein a material of the metal oxide semiconductor layer is IGZO.

16. The display device of claim 12, wherein a material of the metal oxide semiconductor layer is IGZO.

17. A fabrication method of an array substrate, comprising:
forming a gate layer comprising a gate on a base substrate;
forming a gate insulating layer on the gate layer;
forming a source layer comprising a source on the gate insulating layer; and
forming a metal oxide semiconductor layer and a pixel electrode layer, the metal oxide semiconductor layer comprising an active layer,
wherein, the source and the pixel electrode layer are respectively in direct contact with the active layer, and a position where the gate is formed in the gate layer corresponds to a position between the source and a contacting portion of the pixel electrode layer with the active layer.

18. The method of claim 17, wherein forming the metal oxide semiconductor layer and the pixel electrode layer comprises:
forming the metal oxide semiconductor layer on the source layer and the gate insulating layer; and
forming the pixel electrode layer on the metal oxide semiconductor layer.

19. The method of claim 18, further comprising:
forming an insulating layer on the metal oxide semiconductor layer before forming the pixel electrode layer on the metal oxide semiconductor layer;
forming a via in the insulating layer so as to partially expose the metal oxide semiconductor layer; and
forming the pixel electrode layer on the metal oxide semiconductor layer, such that the pixel electrode layer is in direct contact with the active layer through the via.

20. The method of claim 17, wherein forming the metal oxide semiconductor layer and the pixel electrode layer comprises:
forming the pixel electrode layer on the gate insulating layer, and
forming the metal oxide semiconductor layer on the source layer, the gate insulating layer and the pixel electrode layer.
